(19) United States
(12) Patent Application Publication
(10) Pub. No.: US 2006/0240651 A1
(43) Pub. Date: Oct. 26, 2006

(54) Methods and apparatus for adjusting ion implant parameters for improved process control

(75) Inventors: Anthony Renau, West Newbury, MA (US); Dennis Rodier, Francestown, NH (US); Joseph C. Olson, Beverly, MA (US); Bret W. Adams, Newburyport, MA (US)

Correspondence Address: Varian Semiconductor Equipment Associates, Inc., 35 Dory Road, Gloucester, MA, 01930, US

(73) Assignee: Varian Semiconductor Equipment Associates, Inc., Gloucester, MA (US)

(21) Appl. No.: 11/114,593

(22) Filed: Apr. 26, 2005

(51) Int. Cl. H01L 21/425

(52) U.S. Cl. 438/527

(57) ABSTRACT

A method for processing a substrate, such as a semiconductor wafer, includes performing a measurement to determine a substrate parameter distribution to be compensated, determining an adjusted implant parameter distribution to compensate for the substrate parameter distribution, and implanting the substrate in accordance with the adjusted implant parameter distribution. The substrate parameter distribution to be compensated may result from another process step and may be uniform or non-uniform. In another embodiment, an implant parameter may be varied as a function of implant position on the substrate to achieve different substrate parameter values in different areas of the substrate.

### FIELD OF THE INVENTION

This invention relates to ion implantation of substrates, such as semiconductor wafers, and, more particularly, to methods and apparatus for adjusting ion implant parameters for improved process control. In some embodiments, an implant parameter distribution may be adjusted in response to a substrate parameter distribution that results from another process step and that does not meet specification. The substrate parameter distribution to be compensated may be uniform or non-uniform as a function of implant position on the substrate. In other embodiments, an implant parameter may be varied as a function of implant position on the substrate to achieve different substrate parameter values in different areas of the substrate.

### BACKGROUND OF THE INVENTION

The processing of substrates, such as semiconductor wafers, for the manufacture of microelectronic circuits involves multiple processing steps in multiple processing tools. Such processing steps include but are not limited to ion implantation, etching, deposition, annealing and photolithography, each of which may be performed several times in the fabrication of a complex wafer. As is well known, the trend is toward fabrication of integrated circuits on large wafers, such as wafers that are 300 millimeters in diameter. Furthermore, the circuits fabricated on the wafers are becoming increasingly complex and circuit feature sizes are decreasing. As a result of these trends, the number of processing steps involved in wafer fabrication increases, and increasingly strict requirements are placed on each of the process steps.

In order to produce integrated circuits with consistent operating characteristics, wafer parameter values must be uniform over the area of the wafer. Thus, various process steps may require uniformity variations of less than one percent. Further, the uniformity requirements become more stringent as integrated circuits increase in complexity. The conventional approach has been to require a high degree of uniformity in each process step, so that the resulting final product also has a high degree of uniformity. The required degree of uniformity can be extremely difficult to achieve in many instances.

In addition, wafer parameter values in one or more process steps may fail to meet specification, despite the fact that the wafer parameter values are uniform over the area of the wafer. The resulting integrated circuits likewise may not meet specification. In general, wafer parameter values may deviate from specification and may be non-uniform over the area of the wafer.

One conventional process step is ion implantation for introducing conductivity-altering impurities into semiconductor wafers. A desired impurity material is ionized in an ion source, the ions are accelerated to form an ion beam of prescribed energy and the ion beam is directed at the surface of the wafer. The energetic ions in the beam penetrate into the bulk of the semiconductor material and are embedded into the crystalline lattice of the semiconductor material to form a region of desired conductivity.

Ion implantation systems usually include an ion source for converting a gas or a solid material into a well-defined ion beam. The ion beam is mass analyzed to eliminate undesired ions species, is accelerated to a desired energy and is directed onto a target plane. The beam may be distributed over the target area by beam scanning, by target movement or by a combination of beam scanning and target movement.

Uniform implantation of ions over the surface of the semiconductor wafer is an important requirement in most applications. As semiconductor device geometries decrease in size and wafer diameters increase, device manufacturers demand minimal dose variation over large surface areas. Techniques for achieving uniform ion implantation are disclosed, for example, in U.S. Pat. No. 6,710,359 issued Mar. 23, 2004 to Olson et al.; U.S. Pat. No. 4,922,106 issued May 1, 1990 to Berrian et al.; U.S. Pat. No. 4,980,562 issued Dec. 25, 1990 Berrian et al.; and U.S. Pat. No. 6,580,083 issued Jun. 17, 2003 to Berrian. In some implanters, the ion beam scan speed may be adjusted as a function of position on the wafer to achieve uniform dose distribution.

U.S. Pat. No. 6,828,204 issued Dec. 7, 2004 to Renau discloses a method and system to compensate for anneal non-uniformities by implanting dopant in a pattern to provide higher dopant concentrations where the anneal non-uniformities result in lower active dopant concentrations.

In most prior art approaches to fabrication of semiconductor wafers, each process step has been treated independently. That is, each process step in the fabrication sequence is required to meet strict uniformity and process variation specifications, so that the final product will also meet specification. As semiconductor wafers become larger and more complex, the cost and difficulty of meeting performance specifications increases.

In the development of integrated circuits, it is frequently necessary to vary process conditions in order to determine optimum process parameter values or device parameter values. Design of experiments (DOE) in R&D and production facilities has required that a single wafer be used for each data point in an experiment. If a developer wants to conduct an experiment with multiple different parameter values, a number of wafers equal to the number of different parameter values is required. The cost of wafers, particularly large diameter wafers, is prohibitive for optimizing process or device parameters with a large number of different parameter values.

Accordingly, there is a need for new and improved methods and apparatus for controlling the fabrication of substrates, such as semiconductor wafers.

### SUMMARY OF THE INVENTION

According to a first aspect of the invention, a method is provided for ion implantation of a substrate. The method comprises implanting the substrate by varying an implant parameter as a function of position on the substrate to compensate for a non-uniform substrate parameter that results from another process step.

The substrate may be implanted by directing an ion beam at the substrate and varying one or more implant parameters as a function of ion beam position on the substrate. Implant parameters, including but not limited to ion beam energy, ion beam current, ion dose, ion beam profile, tilt angle and twist angle, can be varied as a function of ion beam position on the substrate. The ion beam, the substrate, or both can be scanned to distribute the ion beam over the substrate, and a scan parameter, such as scan speed, can be varied as a function of ion beam position on the substrate.

According to a second aspect of the invention, a method for processing a substrate is provided. The method comprises performing a measurement to determine a non-uniform substrate parameter distribution to be compensated, determining a non-uniform implant parameter distribution to compensate for the non-uniform substrate parameter distribution, and implanting the substrate in accordance with the non-uniform implant parameter distribution.

According to a third aspect of the invention, a method for ion implantation of a substrate is provided. The method comprises adjusting an implant parameter distribution in response to a substrate parameter distribution that results from another process step, and implanting the substrate in accordance with the adjusted implant parameter distribution.

The implant parameter distribution and the substrate parameter distribution may be uniform or non-uniform as a function of implant position on the substrate. The implant parameter distribution may be adjusted automatically in response to the substrate parameter distribution.

According to a fourth aspect of the invention, a method for processing a substrate is provided. The method comprises determining a substrate parameter distribution resulting from a process step, adjusting an implant parameter distribution to compensate for the substrate parameter distribution, and implanting the substrate in accordance with the adjusted implant parameter distribution.

In various embodiments, the implant parameter distribution may be adjusted to compensate for one or more of variation in the thickness of a polysilicon film, variation in gate polysilicon critical dimension, variation in gate sidewall offset spacer thickness, and variation in substrate crystal orientation, that result from another process step. In additional embodiments, the implant parameter distribution may be adjusted to compensate for one or more of variation in thickness of a deposited layer, variation in removal of a layer, variation in dose distribution, variation in alignment of a lithographic mask, variation in photoresist thickness, and variation in substrate temperature, that result from another process step.

According to a fifth aspect of the invention, a method is provided for ion implantation of a substrate. The method comprises implanting the substrate by varying an implant parameter as a function of implant position on the substrate to achieve different substrate parameter values in different areas of the substrate. The substrate parameter values in the different areas of the substrate may be evaluated to determine optimum substrate parameter values.

According to a sixth aspect of the invention, a method for processing a substrate is provided. The method comprises defining areas on the substrate, defining implant parameter values for each defined substrate area, and implanting each substrate area according to the defined implant parameter values to achieve different substrate parameter values in different areas of the substrate.

### BRIEF DESCRIPTION OF THE DRAWINGS

For a better understanding of the present invention, reference is made to the accompanying drawings, which are incorporated herein by reference and in which:

FIG. 1 is a simplified flow chart of a process for fabricating semiconductor wafers;

FIG. 2 is a schematic diagram of a semiconductor wafer, illustrating a non-uniform distribution of a wafer characteristic;

FIG. 3 is a flow chart of an implant process in accordance with a first embodiment of the invention;

FIG. 4 is a simplified block diagram of an ion implantation system in accordance with a second embodiment of the invention;

FIG. 5 is a simplified block diagram of an ion implantation system in accordance with a third embodiment of the invention; and

FIG. 6 is a flow chart of an implant process in accordance with a fourth embodiment of the invention.

### DETAILED DESCRIPTION

As used herein, the terms “non-uniform substrate parameter”, “non-uniform distribution” and “non-uniform implant parameter” refer to quantities which are non-uniform over the area of a substrate, i.e., which vary as a function of position on the substrate. A quantity is said to be non-uniform if it does not meet a uniformity specification. The quantity is uniform if it meets the uniformity specification.

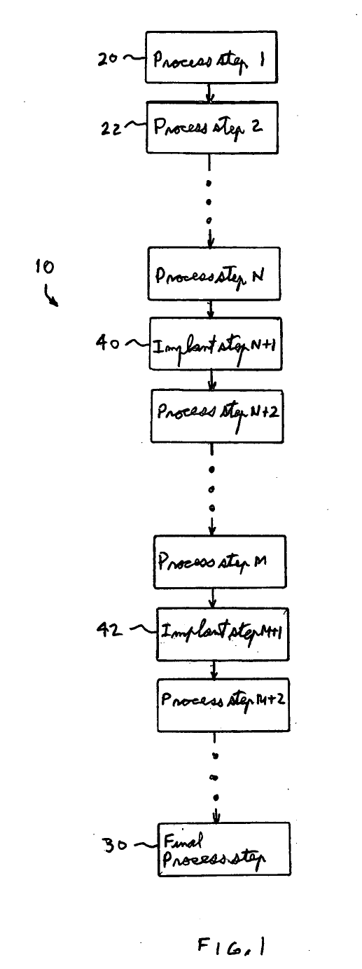

A process for fabricating a substrate is illustrated schematically in FIG. 1. A process 10 includes process steps 20, 22, . . . 30. A practical substrate fabrication process may include on the order of 100 process steps, of which about 15 steps may be implant steps. The example of FIG. 1 includes ion implantation steps 40 and 42. The substrate may be a semiconductor wafer, a flat panel display device or any other substrate that is processed using semiconductor fabrication techniques.

As described above, one or more of the process steps may produce a non-uniform distribution of a substrate parameter. For example, a deposition step may produce non-uniform thickness of a deposited layer over the area of the substrate, an etching step may produce non-uniform removal of the material being etched, or a previous implant step may produce a non-uniform dose distribution. Another example includes lithographic mask misalignment to the wafer. It is sometimes difficult to hold the substrate sufficiently flat during the lithographic step, due to particles on the back side, leading to variations in mask alignment across the substrate. Dose variations or angle variations may be used to compensate for mask misalignment. A further example includes variations in photoresist thickness, requiring compensation for variations due to different amounts of dose being retained in the photoresist or different aspect ratios of a trench in the photoresist requiring different implant angles to deliver the same effective dose. Yet another example is non-uniform substrate temperature, which may occur in an implant or etching step and cause non-uniform diffusion of dopant in the substrate. The non-uniform substrate temperature may be compensated by dose or energy variations.

The process steps which produce non-uniform substrate parameters may occur at any point in process 10, including before an implant step, after an implant step, or both. Non-uniform substrate parameters may result from more than one process step. However, the final substrate following completion of processing should have uniform parameters. It has been recognized that a non-uniform substrate parameter produced by one process step can be compensated in another process step to produce a final substrate that has uniform parameters. The compensation may be performed before or after the process step that produces the non-uniform substrate parameter.

Furthermore, one or more of the process steps may produce a substrate parameter distribution that is uniform but which does not meet specification. Thus, in the example of a deposition step, the thickness of a deposited layer may be uniform over the area of the wafer but may be outside a range of acceptable thickness values. In this instance, the uniform but unacceptable substrate parameter value produced by one process step can be compensated in another process step to produce a final substrate that has parameter values that are both uniform and within specification. The compensation may be performed before or after the process step that produces the unacceptable substrate parameter value. In general, various process steps in the fabrication of a substrate may produce a non-uniform substrate parameter distribution, a uniform substrate parameter distribution that does not meet specification, or both.

According to one aspect of the invention, a semiconductor wafer or other substrate is implanted by adjusting an implant parameter distribution in response to a substrate parameter distribution that results from another process step, and implanting the substrate in accordance with the adjusted implant parameter distribution. The substrate parameter distribution which requires compensation may be uniform or non-uniform. In addition, the implant parameter distribution to compensate for the substrate parameter distribution may be uniform or non-uniform. The process step that produces the substrate parameter distribution to be compensated may occur before, after, or before and after the compensating implant step.

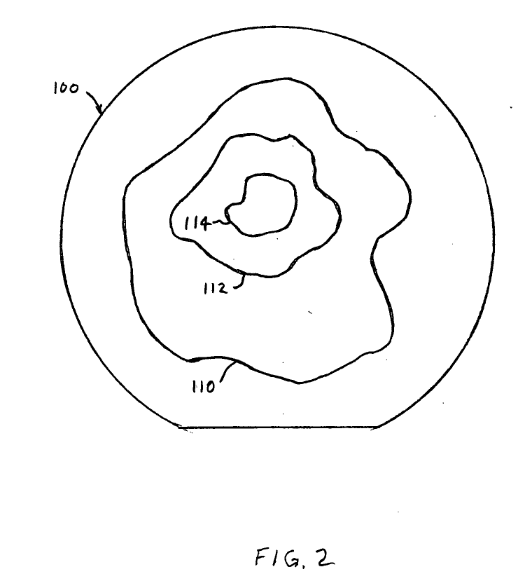

An example of a wafer 100 having a non-uniform wafer parameter distribution is shown in FIG. 2. Contour lines 110, 112 and 114 indicate contours of equal values of the parameter of interest. By way of example only, the wafer parameter of interest may be the thickness of an oxide layer. In general, the wafer parameter may have an arbitrary distribution over the area of the wafer. The arbitrary distribution may be uniform or non-uniform. It will be understood that some distributions may be more difficult than others to compensate effectively. In some instances, the wafer parameter is uniform over the area of the wafer but does not meet specification.

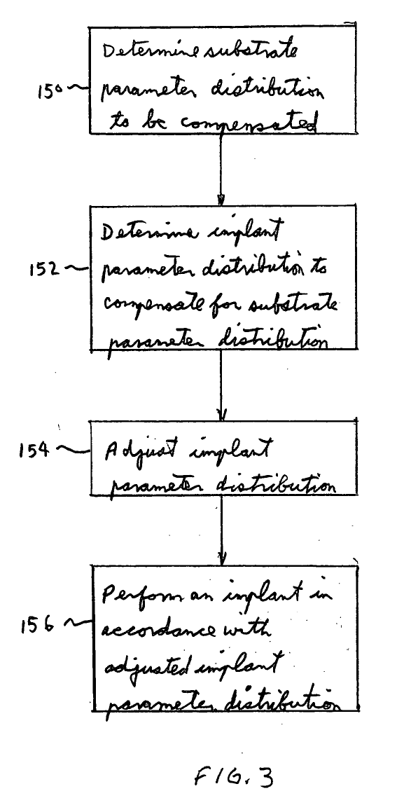

A process for ion implantation in accordance with an embodiment of the invention is shown in FIG. 3. In step 50, the substrate parameter distribution to be compensated is determined, typically by one or more measurements of a substrate and/or a process tool. The substrate parameter distribution to be compensated may be uniform or non-uniform over the area of the wafer. In one example, measurements are performed on a wafer at an appropriate point in the fabrication sequence. Examples of measurements include but are not limited to oxide thickness measurement by ellipsometry, implant dose measurement and electrical test of devices on the wafer. The implant dose measurement may be by Thermawave, which is a laser-based technique for measuring the damage to the silicon crystal structure. In electrical testing of devices on the wafer, one wafer can be taken from a batch and processed to the end of the fabrication line. Electrical parameters of the devices on the wafer are measured to determine corrections to improve the rest of the batch of wafers. The measurements may be analyzed to determine the wafer parameter distribution to be compensated. In another example, measurements are performed on a processing tool that produces a wafer parameter distribution to be compensated. Similarly, the measurements may be analyzed to determine the wafer parameter distribution to be compensated.

The nature of the measurement depends on the wafer parameter distribution to be compensated. In a typical case, the wafer parameter distribution may be more or less constant within a batch of wafers but may vary significantly in different batches or in different types of wafers. In this case, measurements are made on one or more wafers in a batch. In another example, the wafer parameter distribution may be a function of the processing tool and thus may be more or less constant until the tool is changed or adjusted. In this case, a single measurement may be made and used for an extended time. In yet another case, the wafer parameter distribution varies from wafer to wafer. In this case, measurements may be made on each wafer, such as for example sampling a discrete number of points on each wafer.

In step 152, an implant parameter distribution to compensate for the wafer parameter distribution is determined. The compensating implant parameter distribution may be uniform or non-uniform over the area of the wafer. The distribution of the implant parameter may be non-uniform to compensate for a non-uniform wafer parameter distribution, while producing a uniform result. Thus, for example, where an implant is performed through an oxide having a non-uniform thickness, the implant energy may be greater in areas of the wafer where the oxide is thicker and less in areas of the wafer where the oxide is thinner, to produce a uniform implant depth over the area of the wafer. The non-uniform wafer parameter distribution and the compensating implant parameter distribution may have a direct or an inverse relationship, depending on the wafer parameter and the compensating implant parameter.

In step 154, the implant parameter in the implant recipe of the implant controller is adjusted in accordance with the implant parameter distribution determined in step 152. As discussed above, the adjusted implant parameter distribution may be uniform or non-uniform, depending on the implant parameter distribution needed to compensate for the substrate parameter distribution. The adjusted implant parameter distribution may be stored in the implant controller as part of an adjusted implant recipe.

In step 156, an implant is performed using the adjusted implant parameter distribution that was determined in step 152. The implant may be controlled in accordance with the adjusted implant parameter distribution that is stored in the implant controller and accessed in connection with the implant recipe. As indicated above, the adjusted implant parameter distribution may be uniform or non-uniform.

The implant compensation to be performed depends on the nature of the substrate parameter to be compensated and on the type of implanter performing the compensation. In general, implant parameters that can be varied as a function of implant position on the wafer include ion energy, ion current, ion dose, beam scan parameters, mechanical scan parameters, ion beam profile, and the tilt angle and twist angle of the wafer relative to the ion beam. Examples of scan parameters that can be varied include but are not limited to beam scan speed and mechanical scan speed. More than one of the above implant parameters may be varied as a function of implant position on the wafer. In the case where the adjusted implant parameter distribution is uniform, one or more of the above implant parameters are adjusted to desired values.

Different implanter types may be used to perform the compensation. In a first implanter type, the ion beam is scanned in the X direction and the wafer is mechanically translated in the Y direction. In a second implanter type, a fixed ribbon beam is at least as wide as the wafer, and the wafer is mechanically translated orthogonal to the long dimension of the ribbon ion beam. In a third implanter type, the wafer is mechanically translated in two dimensions relative to a fixed spot ion beam. In a fourth implanter type, the ion beam is scanned in two dimensions relative to a fixed wafer. In a different type of ion implantation system, known as a plasma ion implantation system, ions are accelerated from a plasma into the wafer without the need for a beamline.

Spatial compensation can be performed in different ways. The implant parameter can be varied in one direction, such as the X or Y direction. In other embodiments, the implant parameter can be varied in both X and Y directions. In further embodiments, the implant parameter is varied in a radial direction. In general, the implant parameter may have an arbitrary spatial variation, with consideration given to the required throughput and the ability to vary the implant parameter rapidly. While it is desirable to provide exact or nearly exact compensation, it may be beneficial to perform compensation on the basis of a discrete number of implant parameter values in a discrete number of areas on the wafer. Thus, the wafer is divided into N subareas, or pixels, and a compensation value is selected for each of the N subareas. The resolution of the compensation depends on a number of factors, including but not limited to the required uniformity, the impact on throughput and the capabilities of the ion implanter.

Different distributions of non-uniform wafer parameters may be compensated. In general, the wafer characteristic may have an arbitrary variation over the wafer surface. However, the variation may be linear in one or more directions, may be peaked, may be monotonically increasing or decreasing in one or more directions, or may have a repeating pattern. The distribution of the compensating implant and the implant parameter to be varied are selected based on the type of non-uniform wafer parameter and the distribution of the non-uniform wafer parameter.

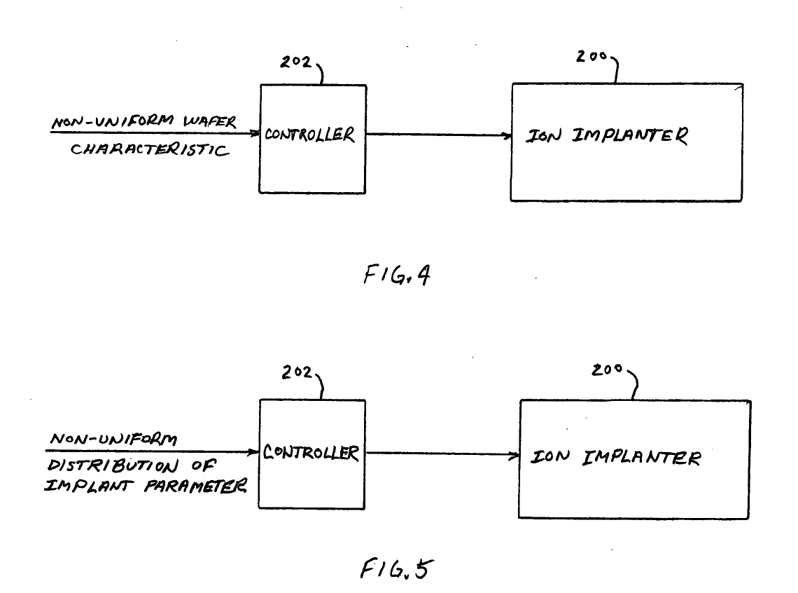

A simplified block diagram of an ion implantation system in accordance with a second embodiment of the invention is shown in FIG. 4. The ion implantation system includes an ion implanter 200 and an implant controller 202. The ion implanter 200 may be any type of ion implanter. The implant controller 202 may be a general purpose computer or a special purpose controller. The ion implanter 200 and the implant controller 202 are typically integrated together to form an ion implantation system.

The implant controller 202 controls ion implanter 200 in accordance with an implant “recipe” for a wafer or a batch of wafers to be implanted. The recipe typically specifies parameters such as ion species, ion energy, ion dose, ion current, tilt angle, twist angle, and the like. In prior art systems, such parameters were controlled to produce a uniform implant. In accordance with aspects of the invention, a wafer parameter distribution to be compensated is input to implant controller 202. The wafer parameter distribution to be compensated may be determined by measurement of one or more wafers or by measurement of a process tool as described above. The wafer parameter distribution may be in the form of a map including values of the parameter and corresponding positions on the wafer.

Implant controller 202 determines the implant parameter distribution to compensate for the wafer parameter distribution. The implant parameter distribution may be determined, for example, from a table that contains wafer parameter values and corresponding implant parameter values. In the example of a non-uniform oxide thickness, the table may contain low ion energy values corresponding to small oxide thickness values and high ion energy values corresponding to large oxide thickness values. The adjusted implant parameter distribution determined by implant controller 202 is used in conjunction with the recipe to control ion implanter 200 during ion implantation of a wafer. The implant parameter is varied in accordance with the adjusted implant parameter distribution to produce a uniform result.

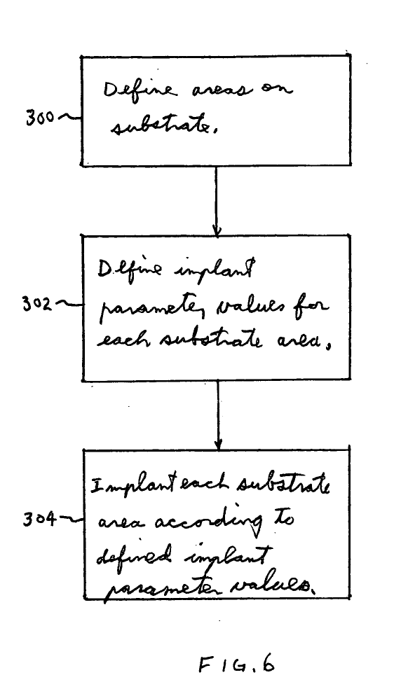

A block diagram of an ion implantation system in accordance with a third embodiment of the invention is shown in FIG. 5. The ion implantation system includes ion implanter 200 and implant controller 202. The embodiment of FIG. 5 differs from the embodiment of FIG. 4 in that the adjusted implant parameter distribution is determined off-line and is input directly to implant controller 202. Implant controller 202 uses the adjusted implant parameter distribution in conjunction with the implant recipe to control ion implanter 200. The adjusted implant parameter distribution is stored in implant controller 202 and, in effect, becomes part of the implant recipe.

The following are specific examples of process control applications in accordance with embodiments of the invention. It will be understood that these applications are given by way of example only and are not limiting as to the scope of the present invention.

Example 1 involves compensation for upstream variation in the thickness of a polysilicon film of the gate electrode. The input from an upstream process may be the thickness of the gate polysilicon, for example, after gate etch. The implant recipe may be adjusted by adjustment of ion implantation energy, dose or other recipe parameter, such as decel ratio in decel mode implantation in the gate polysilicon doping process. The adjusted implant recipe may avoid penetration of gate polysilicon and gate oxide and may achieve better registration of the deep side of the as-implanted profile in the polysilicon to the interface between the gate polysilicon and the gate oxide-dielectric. The results may include avoidance of yield loss, tighter control of device threshold voltage, reduced gate depletion capacitance variation and reduced device drive current variation.

Example 2 involves compensation of upstream variation in the gate polysilicon critical dimension at the substrate and gate polysilicon two-dimensional profile (i.e., vertical sidewall angle) after gate etch. The input from an upstream process may be the gate polysilicon critical dimension and the two dimensional profile after gate etch. The adjustment in implant recipe may be an adjustment of ion implantation energy, dose, tilt angle, twist angle or other recipe parameter in the self-aligned source/drain extension (SDE) and/or halo process. The adjusted implant recipe may compensate for the impact on device short channel effects and electrical L_{eff} from gate critical dimensions variations, may compensate for the impact on the 2D doping profile in the source/drain extension structure, the halo structure (and post anneal channel doping) from variations in the gate edge sidewall angle, and may improve the manufacturing control of the gate overlap dimension. The results may include avoidance of yield loss, tighter control of device threshold voltage, reduced drive current variation and reduced integrated circuit speed variation.

Example 3 involves compensation of upstream variation in the gate sidewall offset spacer thickness just prior to self-aligned source/drain extension and halo implantation. The input from an upstream process may be gate sidewall offset spacer thickness just prior to self-aligned source/drain extension and halo implantation. The adjustment in implant recipe may be adjustment of ion implantation energy, dose, tilt angle, twist angle, or other recipe parameter in the self-aligned source/drain extension and/or halo process. The adjusted implant recipe may compensate for the impact on device short channel effects and electrical L_{eff} from gate sidewall offset spacer thickness variations, may compensate for the impact on the 2D doping profile in the source/drain extension structure and the halo structure (and post anneal channel doping) from variations in gate sidewall offset spacer thickness variations, and may improve the manufacturing control of the gate overlap dimension. The results may include avoidance of yield loss, tighter control of device threshold voltage, reduced device drive current variation and reduced integrated circuit speed variation.

Example 4 involves compensation of upstream variation in the crystal substrate orientation (i.e., for a crystal cut error). The input from an upstream process may be the starting wafer crystal substrate orientation (i.e., error from desired surface normal Miller index direction). The adjustment in implant recipe may be an adjustment of ion implantation energy, dose, tilt angle, twist angle or other recipe parameter in some or all of the well isolation doping processes. The adjusted implant recipe may compensate for the impact on doping vertical and lateral doping profiles from variations in the channeling effect (caused by variations in the crystal orientation) during some or all of the well doping processes. The results may include avoidance of yield loss, tighter control of device threshold voltage, reduced device drive current variation, reduced source drain capacitance variation (i.e., integrated circuit speed variation), reduced variation in latch-up trigger current, reduced variation in vertical and horizontal isolation diode leakage in breakdown voltages (e.g., n+ to p+ lateral diode leakage and breakdown).

The discussion thus far has focused on improvement of wafer fabrication processes by identifying a substrate parameter distribution that does not meet specification or is non-uniform, adjusting an implant parameter distribution to compensate for the substrate parameter distribution, and performing an implant in accordance with an adjusted implant parameter distribution. The substrate parameter distribution to be compensated and the adjusted implant parameter distribution may be uniform or non-uniform, depending on circumstances. However, in each case the goal is a final substrate with substrate parameters which are both uniform and within specification.

According to another aspect of the invention, one or more implant parameters may be varied as a function of implant position on the substrate to achieve different substrate parameter values in different areas of the substrate. Thus, if an integrated circuit developer wants to conduct an experiment with multiple different implant parameter values, the different implant parameter values can be assigned to different areas of a single wafer. Devices in the different areas can be evaluated to determine optimum process parameter values or device parameter values. As a result, multiple different parameter values can be evaluated on a single wafer, and cost is reduced.

A process for fabricating a test wafer in accordance with an embodiment of the invention is shown in FIG. 6. In step 300, areas on the substrate are defined for ion implantation with different parameter values. The areas may have any convenient size and shape. In one example, wedge-shaped areas are defined. In another example, stripes of a specified width may be defined on the substrate. The stripe configuration may be advantageous in the case of an ion implanter that utilizes mechanical scanning. The number of areas and the sizes of the areas depend upon the number of parameter values to be tested and the resolution with which different areas on the substrate can be implanted with different parameter values.

In step 302, implant parameter values for each of the substrate areas are defined. The implant parameter values may be established according to a test protocol and input to the implant controller. As indicated above, one or more implant parameters, such as ion energy, ion dose, ion current, tilt angle and twist angle may be specified in each different area of the substrate.

In step 304, each substrate area is implanted according to the implant parameter values defined in step 302. The resulting wafer includes different substrate parameter values in different areas of the substrate. Accordingly, the effect of the different substrate parameter values can be evaluated by the developer.

Having described several embodiments and an example of the invention in detail, various modifications and improvements will readily occur to those skilled in the art. Such modifications and improvements are intended to be within the spirit and the scope of the invention. Furthermore, those skilled in the art would readily appreciate that all parameters listed herein are meant to be exemplary and that actual parameters will depend upon the specific application for which the system of the present invention is used. Accordingly, the foregoing description is by way of example only and is not intended as limiting. The invention is limited only as defined by the following claims and their equivalents.

What is claimed is:

1. A method for ion implantation of a substrate, comprising:
implanting the substrate by varying an implant parameter as a function of implant position on the substrate to compensate for a non-uniform substrate parameter that results from another process step.

2. A method as defined in claim 1, wherein implanting the substrate includes directing an ion beam at the substrate and varying one or more of the ion beam energy, the ion beam current, the ion dose, the ion beam profile, the tilt angle of the substrate relative to the ion beam, and the twist angle of the substrate relative to the ion beam, as a function of ion beam position on the substrate.

3. A method as defined in claim 1, wherein implanting the substrate includes directing an ion beam at the substrate, scanning at least one of the ion beam and the substrate, and varying a scan parameter as a function of ion beam position on the substrate.

4. A method as defined in claim 1, wherein implanting the substrate includes directing an ion beam at the substrate, the ion beam having a non-uniform beam profile selected to compensate for the non-uniform substrate parameter.

5. A method for processing a substrate, comprising:
performing a measurement to determine a non-uniform substrate parameter distribution to be compensated;
determining a non-uniform implant parameter distribution to compensate for the non-uniform substrate parameter distribution; and
implanting the substrate in accordance with the non-uniform implant parameter distribution.

6. A method as defined in claim 5, wherein implanting the substrate includes directing an ion beam at the substrate and varying one or more of the ion beam energy, the ion beam current, the ion dose, the ion beam profile, the tilt angle of the substrate relative to the ion beam, and the twist angle of the substrate relative to the ion beam, as a function of ion beam position on the substrate.

7. A method as defined in claim 5, wherein implanting the substrate includes directing an ion beam at the substrate, scanning at least one of the ion beam and the substrate, and varying a scan parameter as a function of ion beam position on the substrate.

8. A method as defined in claim 5, wherein implanting the substrate includes directing an ion beam at the substrate, the ion beam having a non-uniform beam profile selected to compensate for the non-uniform substrate characteristic.

9. A method as defined in claim 5, wherein performing a measurement comprises measuring the substrate parameter distribution to be compensated on a semiconductor wafer.

10. A method as defined in claim 5, wherein performing a measurement comprises performing a measurement of a processing tool that produces the non-uniform substrate parameter distribution to be compensated.

11. A method for ion implantation of a substrate, comprising:
adjusting an implant parameter distribution in response to a substrate parameter distribution that results from another process step; and
implanting the substrate in accordance with the adjusted implant parameter distribution.

12. A method as defined in claim 11, wherein the implant parameter distribution and the substrate parameter distribution are non-uniform as a function of implant position on the substrate.

13. A method as defined in claim 11, wherein the implant parameter distribution and the substrate parameter distribution are uniform as a function of implant position on the substrate.

14. A method as defined in claim 11, wherein the implant parameter distribution is automatically adjusted in response to the substrate parameter distribution.

15. A method for processing a substrate, comprising:
determining a substrate parameter distribution resulting from a process step;
adjusting an implant parameter distribution to compensate for the substrate parameter distribution; and
implanting the substrate in accordance with the adjusted implant parameter distribution.

16. A method as defined in claim 15, wherein determining a substrate parameter distribution comprises measuring the substrate parameter distribution.

17. A method as defined in claim 15, wherein adjusting comprises automatically adjusting the implant parameter distribution.

18. A method as defined in claim 15, wherein adjusting comprises adjusting an implant parameter distribution to compensate for variation in the thickness of a polysilicon film that results from another process step.

19. A method as defined in claim 15, wherein adjusting comprises adjusting an implant parameter distribution to compensate for variation in gate polysilicon critical dimension that results from another process step.

20. A method as defined in claim 15, wherein adjusting comprises an implant parameter distribution to compensate for variation in gate sidewall offset spacer thickness that results from another process step.

21. A method as defined in claim 15, wherein adjusting comprises adjusting an implant parameter distribution to compensate for variation in substrate crystal orientation that results from another process step.

22. A method as defined in claim 15, wherein adjusting comprises adjusting an implant parameter distribution to compensate for one or more of variation in thickness of a deposited layer, variation in removal of a layer, variation in dose distribution, variation in alignment of a lithographic mask, variation in photoresist thickness, and variation in substrate temperature, that result from another process step.

23. A method for ion implantation of a substrate, comprising:
implanting the substrate by varying an implant parameter distribution as a function of implant position on the substrate in response to a non-uniform process value.

24. A method as defined in claim 23, wherein the non-uniform process value results from another process step.

25. A method as defined in claim 23, wherein the implant parameter distribution is preprogrammed to achieve different substrate parameter values in different areas of the substrate.

26. A method for ion implantation of a substrate, comprising:
implanting the substrate by varying an implant parameter as a function of implant position on the substrate to achieve different substrate parameter values in different areas of the substrate.

27. A method as defined in claim 26, wherein implanting the substrate includes directing an ion beam at the substrate and varying one or more of the ion beam energy, the ion beam current, the ion dose, the ion beam profile, the tilt angle of the substrate relative to the ion beam, and the twist angle of the substrate relative to the ion beam, as a function of ion beam position on the substrate.

28. A method as defined in claim 26, wherein implanting the substrate includes directing an ion beam at the substrate, scanning at least one of the ion beam and the substrate, and varying a scan parameter as a function of ion beam position on the substrate.

29. A method for processing a substrate, comprising:
defining areas on the substrate;
defining implant parameter values for each defined substrate area; and
implanting each substrate area according to the defined implant parameter values to achieve different substrate parameter values in different areas of the substrate.

30. A method as defined in claim 29, wherein implanting each substrate area includes directing an ion beam at the substrate and varying one or more of the ion beam energy, the ion beam current, the ion dose, the ion beam profile, the tilt angle of the substrate relative to the ion beam and the twist angle of the substrate relative to the ion beam, in different areas of the substrate.
